(19) United States
(12) Patent Application Publication
(10) Pub. No.: US 2014/0300411 A1
(43) Pub. Date: Oct. 9, 2014

(54) Apparatus and method for removing mechanical resonance with internal control Loop

(71) Applicant: shmuel livne, Yehud (IL)

(72) Inventor: shmuel livne, Yehud (IL)

(21) Appl. No.: 13/855,750

(22) Filed: Apr. 3, 2013

(51) Int. Cl. H03H 11/04

(52) U.S. Cl. CPC H03H 11/0405
USPC 327/552

(57) ABSTRACT

The present invention related to an apparatus and method to removing mechanical resonance of a system using internal control loop, and in more particularly, the internal control loop reduces the resonance factor of the system. The approach in the present invention is not sensitive to the system mechanical parameters changes within time and within temperature changes. The approach in the present invention creates mechanical platform with modified equation that have ξ greater than 0.5 which eliminate the mechanical resonance from the system response. The system with resonance response can base on platform that includes the following components: MEMS devices, DC/AC motors and more.

### BACKGROUND OF THE INVENTION

1. Field of the invention

The present invention related to an apparatus and method to removing mechanical resonance of a second order system using internal control loop, and in more particularly, the internal control loop reduces the resonance factor of the system.

The second order system with resonance response can base on platform that includes the following components: MEMS devices, DC /AC motors and more.

2. Description of the related Art

Generally, System which contains mechanical components corresponds to the following equation (1):

$$H ( s ) = \frac{{K}_{2}}{\frac{{S}^{2}}{{W}_{n}^{2}} + \frac{2 * ξ * S}{{W}_{n}} + 1} \qquad ( 1 )$$

K₂—refer to the system gain, Wₙ—refer to resonance frequency, ξ—refer to the resonance factor. Second order system with resonance factor ξ less than 0.5 may have response with resonance. Second order systems with mechanical components with resonance factor ξ less than 0.5 are: system which contains motor, system which contains Mechanical Electro Micro System (MEMS), and many more systems that corresponding like equation (1) that has ξ less than 0.5.

The second order system with resonance factor less than 0.5 may provide undesired response that includes resonance response. The resonance response is a problem that reduces the system performance.

Most solutions for the system mechanical resonance are based on notch filter techniques. The notch filters techniques must have an option of adaptive parameters changing according to the system mechanical parameters changes in time and in temperature.

The approach in the present invention is not sensitive to the system mechanical parameters changes in time and in temperature. The approach in the present invention creates mechanical platform with modified equation that has ξ greater than 0.5 which eliminate the mechanical resonance from the system response.

### SUMMARY OF THE INVENTION

The present invention approach is based on changing the mechanical platform system resonance factor by internal control loop. The resonance factor changes by internal loop to resonance factor greater than 0.5 which removes from system response the resonance response.

The invention present how system with platform that behave as described in equation (1) changes by internal loop as described in FIG. 2).

The second order platform like MEMS device described in equation (1) have 2 more blocks, K1 presents the drive gain to the second order platform and K2 presents the second order platform sensing response gain.

The open loop second order system equation presents in equation (2).

$${H}_{open\_loop} ( s ) = \frac{{K}_{1} * {K}_{2} * {K}_{3}}{\frac{{S}^{2}}{{W}_{n}^{2}} + \frac{2 * ξ * S}{{W}_{n}} + 1} \qquad ( 2 )$$

The internal loop feedback B as presented in FIG. 2) in equation (3).

B(s)=K₄*S (3)

The Platform after the change with the internal loop describes in equation (4).

$${A}_{ch} ( s ) = \frac{A}{1 + A * B} \qquad ( 4 )$$

The modified platform Ach(S) described in details as presented in the following 3 equations (5), (6) and (7).

$$\begin{matrix}{A}_{ch} ( s ) = \frac{\frac{{K}_{1} * {K}_{2} * {K}_{3}}{\frac{{S}^{2}}{{W}_{n}^{2}} + \frac{2 * ξ * S}{{W}_{n}} + 1}}{1 + ( \frac{{K}_{1} * {K}_{2} * {K}_{3}}{\frac{{S}^{2}}{{W}_{n}^{2}} + \frac{2 * ξ * S}{{W}_{n}} + 1} ) * ( {K}_{4} * S )} & ( 5 ) \\ {A}_{ch} ( s ) = \frac{{K}_{1} * {K}_{2} * {K}_{3}}{\frac{{S}^{2}}{{W}_{n}^{2}} + \frac{2 * ξ * S}{{W}_{n}} + 1 + ( {K}_{1} * {K}_{2} * {K}_{3} ) * ( {K}_{4} * S )} & ( 6 ) \\ {A}_{ch} ( s ) = \frac{{K}_{1} * {K}_{2} * {K}_{3}}{\frac{{S}^{2}}{{W}_{n}^{2}} + ( \frac{2 * ξ}{{W}_{n}} + {K}_{1} * {K}_{2} * {K}_{3} * {K}_{4} ) S + 1} & ( 7 )\end{matrix}$$

The modified resonance factor ξ_{ch} presents in equation (8).

$${ξ}_{ch} = ξ + \frac{{K}_{1} * {K}_{2} * {K}_{3} * {K}_{4} * {W}_{n}}{2} \qquad ( 8 )$$

The ξ_{ch} can be adjusted with K4 and become greater than 0.5, which eliminate the mechanical resonance from the system response.

### BRIEF DESCRIPTION OF THE DRAWINGS

Those and/or other aspects and advantages of the present invention will become more readily appreciated from the following description of the embodiments, taken in conjunction with the accompanying drawings of which:

FIG. 1 is a common control system with second order platform (A) and feedback (B).

FIG. 2 is the modified second order platform (Ach) with internal loop feedback K4*S.

FIG. 3 is an example of modified second order platform (Ach) open loop.

FIG. 4 is the Bode diagram of the second order platform (A) the top graph is the Gain graph in dB and the lower graph is the phase graph in degrees.

FIG. 5 is the second open platform (A) responses in time to input of pulse signal, the response contains the resonance effect.

FIG. 6 is an example of modified second order platform (Ach) close loop.

FIG. 7 is the Bode diagram of the modified second order platform (Ach), the top graph is the Gain graph in dB and the lower graph is the phase graph in degrees.

FIG. 8 is the modified second order platform (Ach) responses in time to input of pulse signal, the response does not contain the resonance effect.

FIG. 9 is the modified internal feedback for the modified second order platform (Ach) with second order Butterworth low pass filter.

FIG. 10 is Bode diagram of the internal loop feedback for the modified second order platform (Ach), the top graph is the Gain graph in dB and the lower graph is the phase graph in degrees.

FIG. 11 is Bode diagram of the modified internal loop feedback with second order Butterworth low pass filter for the modified second order platform (Ach), the top graph is the Gain graph in dB and the lower graph is the phase graph in degrees.

FIG. 12 is analog circuits implementation of the internal loop feedback, the top figure implemented the K*S and the lower figure implemented the K3*(K4*S)/(1+K4*S).

FIG. 13 is modified second order platform (Ach) with PI (Proportional and Integrator) controller block and proportional main feedback (Gain 2=1).

FIG. 14 is responses in time for input of pulse signal to modified second order platform (Ach) with PI (Proportional and Integrator) controller block and proportional main feedback (Gain2=1), the response does not contain the resonance effect.

FIG. 15 is the responses in time for input of pulse signal to second order platform (A) without the internal feedback and with PI (Proportional and Integrator) control block and proportional main feedback (Gain2=1), the response contains the resonance effect.

### DETAILES DESCRIPTION OF THE INVENTION

Reference will now be made in detail to the embodiments of the present invention, with examples of which are illustrated in the accompanying drawings, wherein reference indications refer to the elements throughout the figures.

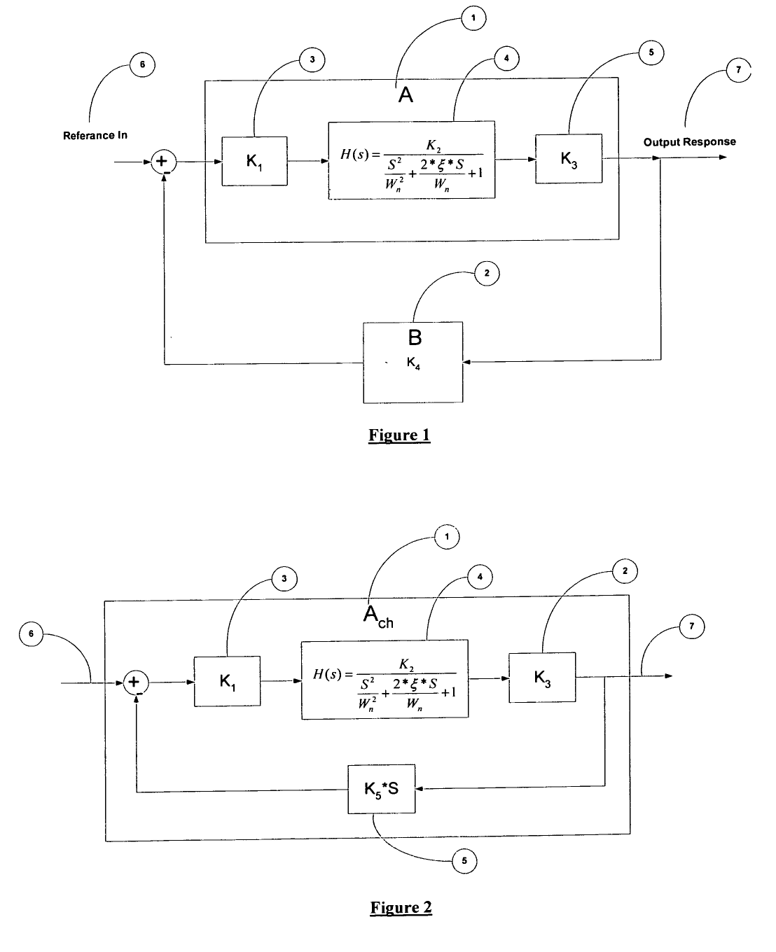

The embodiments which described below explain the present invention by referring to the figures. FIG. 1 shows a simple common control loop for Platform contains second order process (FIG. 1.4) with ξ less than 0.5. The second order process can be MEMS (Micro Electro Mechanical System) device, Motor motion system, and more.

K₁ (FIG. 1.3) describes the driver to the second order process (FIG. 1.4).
K₃ (FIG. 1.5) describe the sense circuit of the second order process (FIG. 1.4) that translate the Platform output for example from position to voltage.

Elements (FIG. 1.3), (FIG. 1.4) and (FIG. 1.5) create the Platform [A] (FIG. 1.1) within common control loop (FIG. 1), where the input and the output to Platform A (FIG. 1.1) can be in any units, in the present invention to simplify the explanation the input and output units to Platform [A] (FIG. 1.1) are in voltage units.

The output response in (FIG. 1.7) is not in all cases the desired response of the common control loop (FIG. 1) which contains second order process (FIG. 1.4).

K₄ (FIG. 1.2) describes the control feedback B of the common control loop (FIG. 1).

The input to common control loop (FIG. 1) is the Reference In (FIG. 1.6). The Reference In (FIG. 1.6) can be in any type, in the present invention to simplify the explanation the input to the common control loop (FIG. 1) is in voltage type.

FIG. 2 shows the modified Platform A_{ch} (FIG. 2.1) that contains the internal loop. The internal loop K₅*S (FIG. 2.5) have effect that describe in the above equations 4, 5, 6, 7, and 8 on the modified Platform A_{ch} (FIG. 2.1), and change ξ the in the second order process (FIG. 1.4) to new ξ_{ch} as described above in equation 8.

The changed new ξ_{ch} defines with K₅ to become greater than 0.5, which eliminate the mechanical resonance from the system response.

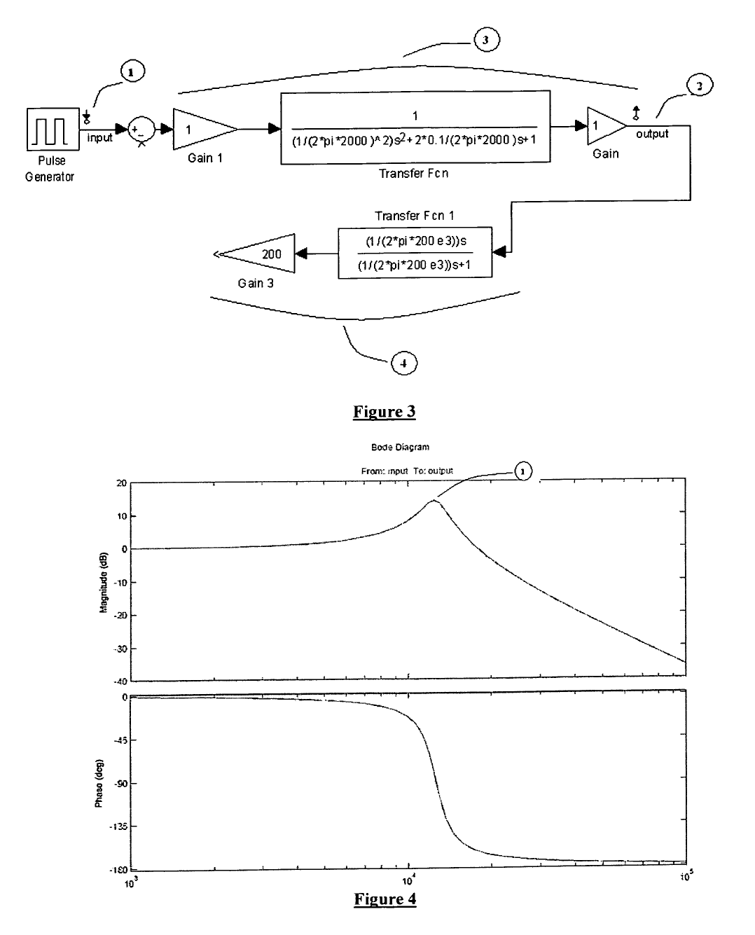

FIG. 3 shows example of which are illustrated the second order process (FIG. 1.4) mechanical resonance response. The parameters for Platform A (FIG. 1.1) are: K₁ (FIG. 1.3)=1, K₃ (FIG. 1.5)=1, and the resonance frequency Wn=2000 Hz and the resonance factor ξ=0.1 in the second order process (FIG. 1.4). The simulation results of frequency response in FIG. 4, and of time response in FIG. 5 is done for the transfer function second order process (FIG. 3.3), where the input define at point (FIG. 3.1), and the output define at point (FIG. 3.2).

The internal loop feedback (FIG. 3.4) parameters are: K5=200, and the semi derivative frequency=200 KHz which is one of the optional implementation of internal feedback and will be explained later in the next drawings.

FIG. 4 shows the frequency simulation results of the second order process (FIG. 3.3) where the input defines at point (FIG. 3.1) and the output defines at point (FIG. 3.2). The top figure in FIG. 4 is the Gain graph in dB and the lower graph is the phase in degree. In the top graph the Gain graph shows the resonance point (FIG. 4.1) of second order process (FIG. 3.3) and the reason for the resonance response.

FIG. 5 shows the time simulation results for the second order process (FIG. 3.3) where the input defines at point (FIG. 3.1) and the output defines at point (FIG. 3.2). The input signal pulse signal shown in (FIG. 5.1) and the output of the second order process (FIG. 3.3) with the resonance response shown in (FIG. 5.2).

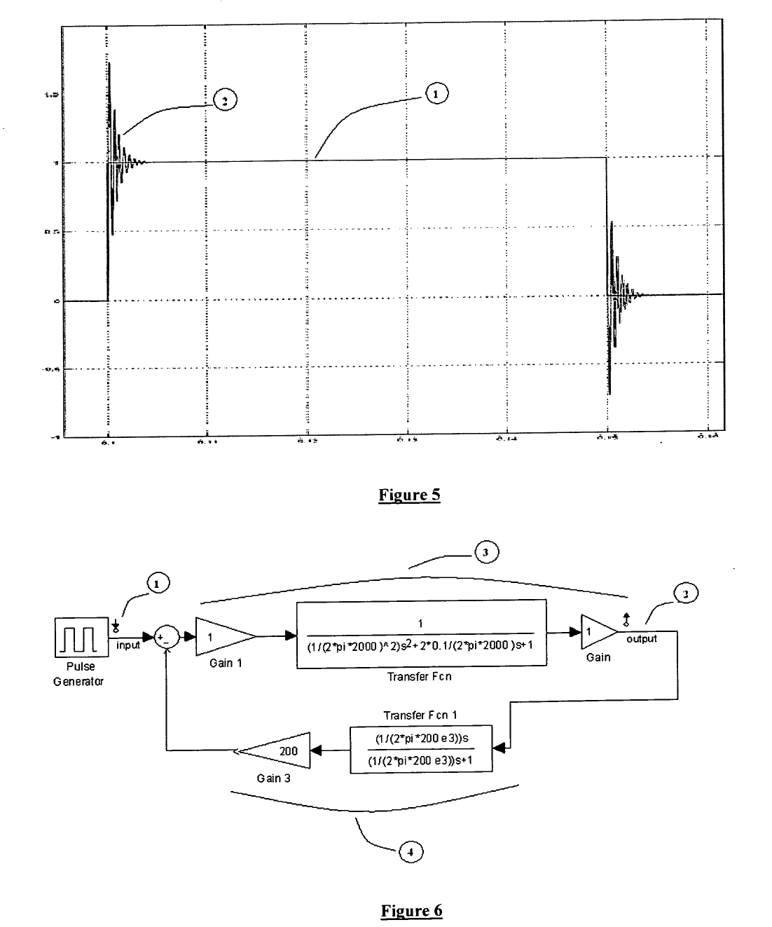

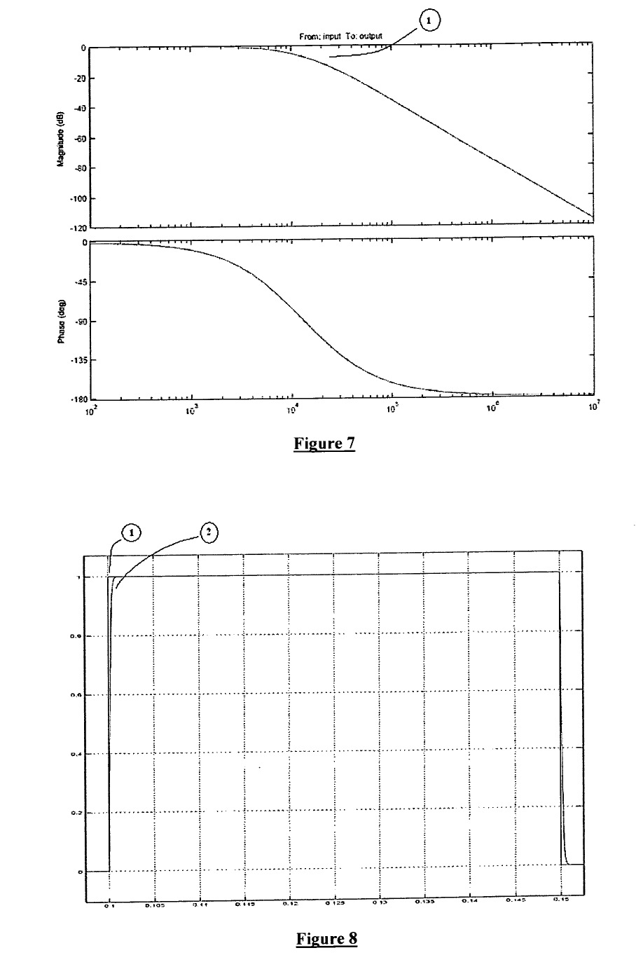

FIG. 6 shows an example of which are illustrated the modified second order platform (Ach) (FIG. 2) with the internal loop that removes the mechanical resonance. The following parameters for Platform Ach (FIG. 2.1) are: K1 (FIG. 2.3)=1, K3 (FIG. 2.2)=1, the resonance frequency Wn=2000 Hz and the resonance Factor ξ=0.1 in the second order process (FIG. 2.4). The simulation results of frequency response in FIG. 7, and the of time response in FIG. 8 in done for the modified transfer function includes second order process with internal loop (FIG. 6.4), where the input defines at point (FIG. 6.1) and the output defines at point (FIG. 6.2).

The internal loop feedback (FIG. 6.4) parameters are: Gain 3 in FIG. 6 defined as 200, and the semi derivative frequency=200 KHz, Those parameters are one of the optional implementation of semi derivative at 2000 Hz which will be explained later in the next drawings.

FIG. 7 shows the frequency simulation results for the modified transfer function including second order process (FIG. 6.3) with internal feedback loop (FIG. 6.4). The input defined at point (FIG. 6.1) and the output defined at point (FIG. 6.2). The top figure in FIG. 7 is the Gain graph in dB and the lower graph is the phase graph in degree. In the top graph the gain graph point (FIG. 7.1) shows that the resonance is not exist in the modified transfer function of second order process in FIG. 6.

FIG. 8 shows the time simulation results for the modified transfer function including second order process (FIG. 6.3) with internal feedback loop (FIG. 6.4). The input defined at point (FIG. 6.1) and the output defined at point (FIG. 6.2). The input signal pulse signal shown in (FIG. 8.1) and the output of the modified transfer function FIG. 6 without the resonance response shown in (FIG. 8.2).

FIG. 9 shows example of the internal loop feedback with LPF (Low Pass Filter). The internal loop K5*S (FIG. 2.5) is ideal derivative which contribute high frequency noise to the control loop FIG. 1. This high frequency noise may cause the control loop not function correctly or to be not stable. For reduce the noise from the internal loop K5*S (FIG. 2.5) the semi derivative internal loop (K*S)/((K*S)+1) as present in (FIG. 6.4) can be used.

The semi derivative (K*S)/((K*S)+1) limited the high frequency noise and may help the control loop to function correctly and to be stable. The Butterworth second order LPF (low Pass Filter) (FIG. 9.2) will help to reduce the high frequency noise and still keep the derivative function at the Wn resonance frequency. The internal loop feedback parameters are: Gain 3 in (FIG. 9.5) defined as 400, the frequency of the semi derivative (K*S)/((K*S)+1) defined as 200 KHz (FIG. 9.4), and the Butterworth second order LPF defined at frequency=5000 Hz (FIG. 9.2).

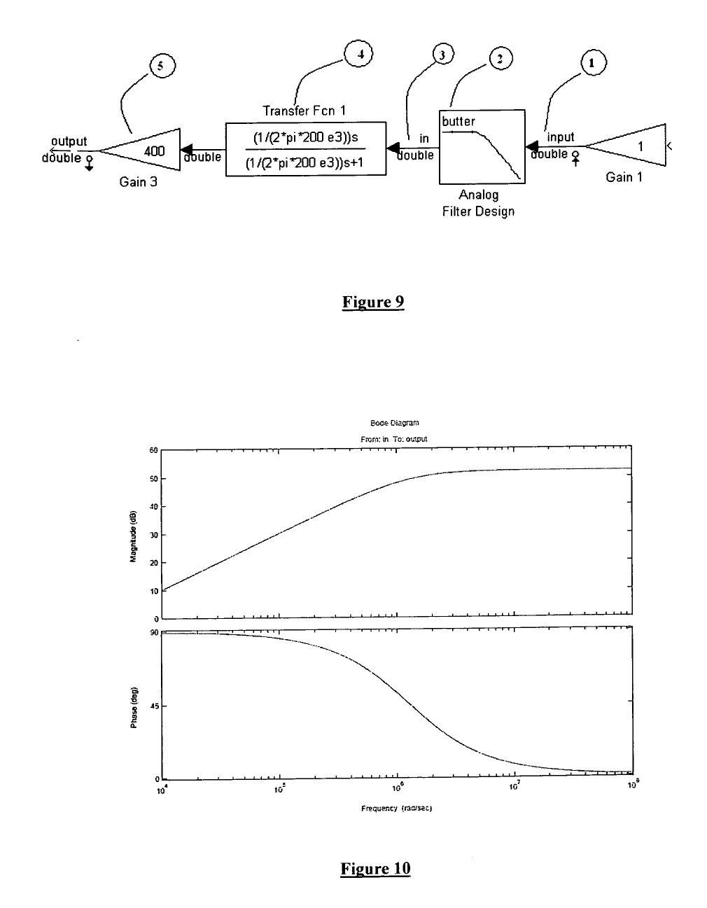

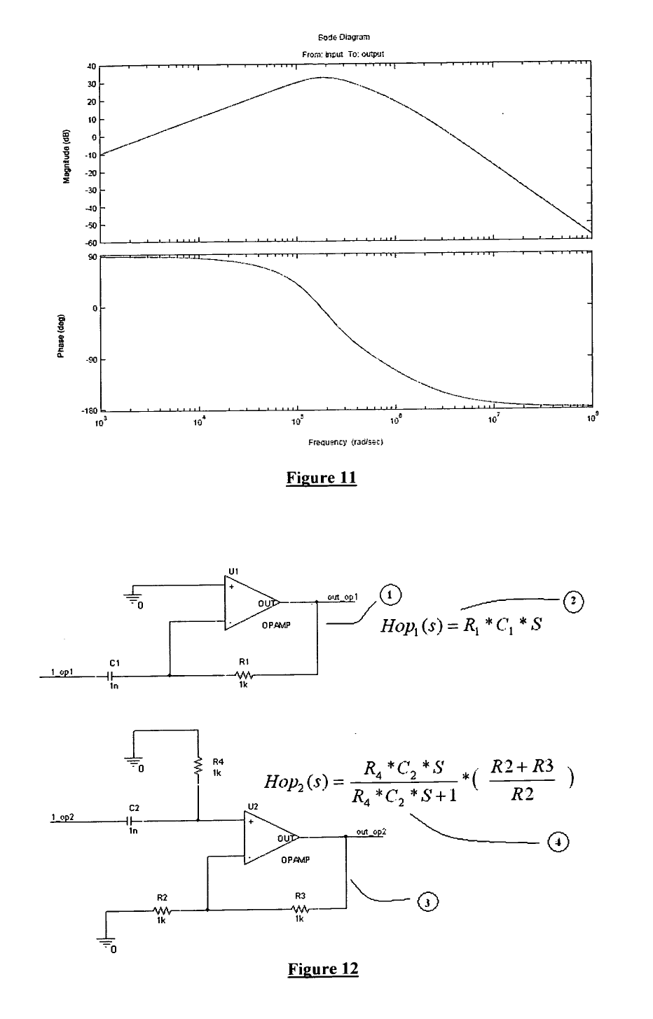

FIG. 10 shows the frequency simulation results for the internal loop transfer function that include semi derivative (FIG. 9.4) and the Gain (FIG. 9.5). The input defines at point (FIG. 9.3) and the output defined at the output of Gain 3 (FIG. 9.5). The top figure in FIG. 10 is the Gain graph in dB and the lower graph is the phase graph in degree. In the top graph the gain graph shows that the high frequency have large gain, which the large gain creates high frequency noise that may cause the control loop not function correctly and to be not stable.

FIG. 11 shows the frequency simulation results for the internal loop transfer function that include semi derivative (FIG. 9.4), the Gain (FIG. 9.5) and the Butterworth second order LPF at 5000 Hz (FIG. 9.2). The input defined at point (FIG. 9.1) and the output defined at the output of Gain 3 (FIG. 9.5). The top figure in FIG. 10 is the Gain graph in dB and the lower graph is the phase graph in degree. In the top graph the gain graph shows that the high frequency reduces the gain, the reduced gain in the high frequency will create less high frequency noise that may help the control loop to function correctly and to be stable.

FIG. 12 shows the implementation of the internal control feedback. The implementation for the true derivative as in equation (3) is implemented as seen in (FIG. 12.1) and the transfer function for this implementation (FIG. 12.1) present in (FIG. 12.2). The implementation for the semi derivative is simple as seen in (FIG. 12.3) and the transfer function the implementation in (FIG. 12.3) present in (FIG. 12.4).

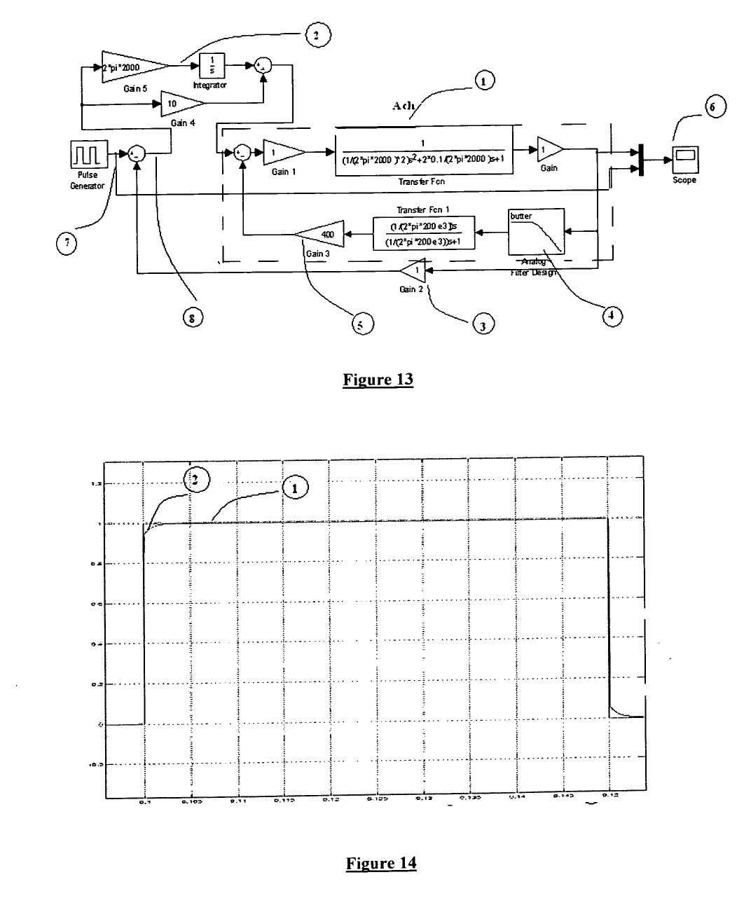

FIG. 13 shows an example of position control system and simulation results with and without the internal loop effect. The position control loop contains controller block of PI (Proportional and Integrator) controller (FIG. 13.2), and second order process with Wₙ resonance frequency=2000 Hz with ξ resonance factor=0.1 present in (FIG. 13.1). The platform with second order process , driver Gain 1=1 present in (FIG. 13.1), sensor Gain=1 present in (FIG. 13.1) and the main feedback loop Gain2=1 present in (FIG. 13.3). The modified second order process with internal loop contains Butterworth filter two poles at 5000 Hz (FIG. 13.4), semi derivative in (Transfer Fcn 1) , and gain at Gain3=400 (FIG. 13.5), which create the modified second order process (FIG. 13.1). The main loop feedback=1 and present in (FIG. 13.3). The input to the position control loop system (FIG. 13) is pulse signal at point (FIG. 13.7).

FIG. 14 presents the simulation result of the modified second order process with internal loop and the gain in Gain 3=400 (FIG. 13.5). The simulation result preset in FIG. 14 two graphs, graph one is the input at (FIG. 13.7) presents the input signal graph in (FIG. 14.1), and the result graph the second graph is the output at (FIG. 13.6) presents the output signal graph in (FIG. 14.2).

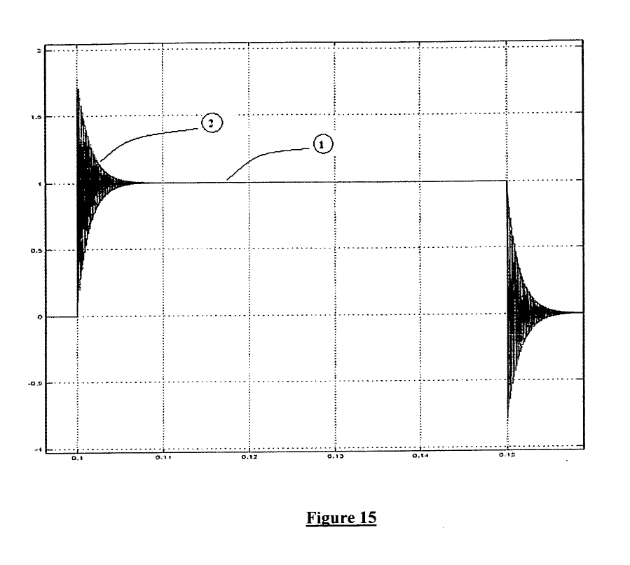

FIG. 15 presents the simulation result of the second order process without internal loop and the gain in Gain 3=0 (FIG. 13.5). The simulation result preset in FIG. 15 two graphs, graph one is the input at (FIG. 13.7) presents the input signal graph in (FIG. 15.1) and the result graph the second graph is the output at (FIG. 3.6) presents the output signal graph in (FIG. 15.2)

According to an aspect of the present invention as describe above, a potential resonance frequency response of a system is removed by modified the process with internal control loop. The internal loop parameters are not sensitive to changes in process parameters and to ambient or to platform temperature changes.

Aspects of the present invention may be implemented as a method, or an apparatus. Aspects of the present invention may also be embodied in position control system, MEMS control system, and in computer readable medium. The computer readable media includes storage media such as magnetic media (e.g. ROM's Floppy disks hard disks, etc.) and optically readable media (e.g. CD-ROMs, DVDs, etc.).

Although a few embodiments of the present invention have been shown and described, it would be appreciated by those skilled in the art of the changes may be made in this embodiment without departing from the principles and spirit of the present invention defined, the scope of which is defined in the claims and their equivalents. Therefore the scope of the present invention is not determined by the above description but by accompanying claims.

What is claimed is:

1. A mechanical resonance removing apparatus using an internal loop to modified process or platform to remove resonance frequency from process or platform which behaves as second order process, the apparatus comprising:
a) Analog implementation of true derivative (FIG. 12, top) constructs the internal loop.
b) Analog implementation of semi derivative (FIG. 12, bottom) constructs the internal loop.
c) Analog implementation of true or semi derivative with LPF (Low Pass Filter) one or two poles with cutoff frequency close as less than one frequency decade from the resonance frequency as in (FIG. 13) constructs in the internal loop.
d) Digital implementation by IIR (Infinite Impulse Response) or FIR (Finite Impulse Response) of true derivative constructs the internal loop.
e) Digital implementation by IIR (Infinite Impulse Response) or FIR (Finite Impulse Response) of semi derivative constructs the internal loop.
f) Digital implementation of true or semi derivative with LPF (Low Pass Filter) one or two poles with cutoff frequency close as less than one frequency decade from the resonance frequency as in (FIG. 13) constructs the internal loop.

2. The apparatus of claim 1 is using to reduce the settling time in motor position control loop.

3. The apparatus of claim 1 is using to reduce the position control loop of MEMS (Mechanical Electro Micro System) device.

4. The apparatus of claim 1 can be use as compensation of second order system to reduce undesired resonance frequency.

5. The apparatus of claims 2, 3 and 4 wherein second order system comprises mechanical systems.

6. The apparatus of claims 2, 3 and 4 wherein second order system comprises electronic systems.

7. The apparatus of claims 2, 3 and 4 wherein second order system comprises optic systems.

8. The apparatus of claims 1, 5 and 6 wherein second order system comprises systems which include MEMS (Mechanical Electro Micro System) devices.

9. The apparatus of claim 1 wherein internal loop comprises implementation in discrete design or in integrated design like in ASIC, VLSI.
